(19) United States
(12) Patent Application Publication
(10) Pub. No.: US 2011/0114180 A1
(43) Pub. Date: May 19, 2011

(54) METHOD CIRCUIT DEVICE ASSEMBLY AND SYSTEM FOR CONVERTING SOLAR RADIATION INTO ELECTRIC CURRENT

(75) Inventors: Serge Steinblatt, Raanana (IL); Zeev Pritzker, Tel Aviv (IL)

(73) Assignee: SOLECTA LTD., Tel Aviv (IL)

(21) Appl. No.: 13/055,459

(22) PCT Filed: Jul. 23, 2009
(86) PCT No.: PCT/IB2009/053211

§ 371 Date: Jan. 23, 2011

Related U.S. Application Data
(60) Provisional application No. 61/082,832, filed on Jul. 23, 2008.

(51) Int. Cl. H01L 31/0232; H01L 31/0224

(52) U.S. Cl. 136/259; 136/256

(57) ABSTRACT

Disclosed is a (solar) light electrical power generation unit including a concentrator plane of one or more photo-concentrator structures and a conversion surface including one or more photovoltaic (“PV”) active regions. The conversion surface is substantially parallel to the concentrator plane, and actuators may adjust a relative position between the concentrator plane and the conversion surface while maintaining the parallel relation between the concentrator plane and the conversion surface.

### FIELD OF THE INVENTION

The present invention relates generally to the field of solar energy collection and conversion. More specifically, the present invention relates to method, circuits, device, assemblies and systems for collecting and converting solar radiation into electric current.

### BACKGROUND

The photovoltaic effect was first recognized in 1839 by French physicist A. E. Becquerel. However, it was not until 1883 that the first solar cell was built, by Charles Fritts, who coated the semiconductor selenium with an extremely thin layer of gold to form the junctions. The term “photovoltaic” comes from the Greek φ\tilde{ω}ζ (phōs) meaning “light”, and “voltaic”, meaning electric, from the name of the Italian physicist Volta, after whom a unit of electrical potential, the volt, is named. The term “photo-voltaic” has been in use in English since 1849. The device at that time was only around 1% efficient. Sven Ason Berglund had a number of patents concerning methods of increasing the capacity of these cells. In 1946 Russell Ohl patented the modern junction semiconductor solar cell, which was discovered while working on the series of advances that would lead to the transistor.

The modern age of solar power technology arrived in 1954 when Bell Laboratories, experimenting with semiconductors, accidentally found that silicon doped with certain impurities was very sensitive to light. Daryl Chapin, with Bell Labs colleagues Calvin Fuller and Gerald Pearson, invented the first practical device for converting sunlight into useful electric power. This resulted in the production of the first practical solar cells with a sunlight energy conversion efficiency of around 6 percent. The solar battery was first demonstrated on Apr. 25, 1954. The first spacecraft to use solar panels was the US satellite Vanguard 1, launched in March 1958 with solar cells made by Hoffman Electronics. This milestone created interest in producing and launching a geostationary communications satellite, in which solar energy would provide a viable power supply.

In 1970 the first highly effective GaAs heterostructure solar cells were created by Zhores Alferov and his team in the USSR. Metal Organic Chemical Vapor Deposition (MOCVD, or OMCVD) production equipment was not developed until the early 1980s, limiting the ability of companies to manufacture the GaAs solar cell. In the United States, the first 17% efficient air mass zero (AM0) single-junction GaAs solar cells were manufactured in production quantities in 1988 by Applied Solar Energy Corporation (ASEC). The “dual junction” cell was accidentally produced in quantity by ASEC in 1989 as a result of the change from GaAs on GaAs substrates to GaAs on Germanium (Ge) substrates. The accidental doping of Ge with the GaAs buffer layer created higher open circuit voltages, demonstrating the potential of using the Ge substrate as another cell. As GaAs single-junction cells topped 19% AM0 production efficiency in 1993, ASEC developed the first dual junction cells for spacecraft use in the United States, with a starting efficiency of approximately 20%. These cells did not utilize the Ge as a second cell, but used another GaAs-based cell with different doping. Eventually GaAs dual junction cells reached production efficiencies of about 22%. Triple Junction solar cells began with AM0 efficiencies of approximately 24% in 2000, 26% in 2002, 28% in 2005, and in 2007 have evolved to a 30% AM0 production efficiency, currently in qualification.

Since solar cells, and arrays made thereof (i.e. solar panels), operate at peak conversion efficiency when the angle of incidence between the cell plane and the light rays is 90°, and since the sun continually moves across the sky during the day, maintaining conversion efficiency requires the solar panels to track the sun. The basic principle of sun-tracking and solar-trackers is a well known one. As the sun's position in the sky varies both with the seasons (elevation) and time of day, a solar tracker follows the position of the sun. Tracking can substantially improve the amount of total power produced by a solar power system.

Various types of solar trackers are known. These can be generally categorized into active or passive, and/or single-axis or dual-axis. Single axis trackers usually use a polar mount for maximum solar efficiency and will usually have a manual elevation (axis tilt) adjustment on a second axis which is adjusted at regular intervals throughout the year. Compared to a fixed mount, a single axis tracker may increase annual output by approximately 30%, and a dual axis tracker may increase it by an additional 6%.

Polar trackers have one axis aligned with the North/South direction—hence the name polar. The polar axis should be angled towards South, and the angle between this axis and the horizontal plane should be ideally equal to the geographical latitude. Simple polar trackers with single axis tracking may also have an adjustment along a second axis: the angle of declination (tilt). This allows to angle a panel towards the sun when it is higher in the sky in the summer, or lower in the sky in the winter. In cases where no adjusting of the angle of declination is made during the year, it will be normally set to the local geographical latitude, as that is where the mean annual irradiation is approximately maximized. Occasional or continuous adjustments to the declination compensate for the northward and southward shift in the sun's path as it moves through the seasons over the course of the year.

The solar trackers available today are cumbersome, require relatively large and energy consuming electro-mechanical tracking subsystems and are thus prone to wear and regular failure. This makes them unsuitable for installation on rooftops of residential and commercial buildings. There is therefore a need for solar energy collection and conversion methods, circuits, devices, assemblies and systems that improve solar tracking and solar energy conversion while avoiding use of complex tracking structures with external moving parts, and allow installation on rooftops of residential and commercial buildings.

### SUMMARY OF THE INVENTION

The present invention is a method, circuit, device, assembly and system for converting solar radiation (e.g. sun light) into electrical current. According to some embodiments of the present invention, there may be provided a solar collection assembly including an assembly base, a radiation conversion plane and a radiation concentrator plane. The radiation conversion plane may include a backplane with one or more photovoltaic (“PV”) active regions and may reside between the base and the radiation concentrator plane. According further embodiments of the present invention, the concentrator plane and the assembly may be constructed such that incident light is substantially concentrated on the one or more PV active regions regardless of the angle of incidence of the light with concentrator plane.

According to some embodiments of the present invention, the radiation conversion plane may be composed of a backplane including one or more PV active regions. The PV active regions may be composed of discrete photovoltaic cells mounted on the backplane or may be integral with the substrate, for example grown on the backplane. Any material, composition or method known today or to be devised in the future for producing photovoltaic active regions may be applicable to the present invention. The backplane may include electrically conductive paths composed of electrical wires or printed circuit strips, and at least some of the PV active regions may be electrically interconnected with each other such that electric current produced by the electrically interconnected PV active regions is aggregated and made available through a current output terminal of the backplane and/or assembly.

According to some embodiments of the present invention, the radiation concentrator plane may be made of a photo-permissive or transparent material and may include or be integral with one or more photo-concentrator structures. At least some of the photo-concentrator structures may be adapted to deflect light passing from an outer surface of the structure towards an inner surface of the radiation concentrator plane and onto PV active regions/portions of the radiation conversion plane. According to some embodiments of the present invention, the photo-concentrator structures may be composed of a photo-permissive or transparent material such as glass, quartz, clear plastic or a clear polymer. Any functionally usable material known today or to be devised in the future may be applicable to the present invention.

According to further embodiments of the present invention, a photo-concentrator structure may be formed in a shape adapted to bend incident light rays towards each other. The structure may be formed as semi-cylinders, semi-spheres, synthetic optics (e.g. Fresnel lenses) or any other shape or texture which may bend light so as to produce a light concentration effect. According to some embodiments of the present invention, each given photo-concentrator structure may be adapted to concentrate or focus rays of light striking its outer surface onto a separate given PV active region of the radiation conversion plane, such as a PV active region corresponding to the given photo-concentrator structure.

According to some embodiments of the present invention, the radiation concentrator plane may be supported by, or otherwise connected to, electromechanically adjustable mounts, such that the relative position between the concentrator plane and the converter plane may be adjusted. According to some embodiments of the present invention, the radiation conversion plane may be supported by, or otherwise connected to, electromechanically adjustable mounts, such that the relative position between the concentrator plane and the converter plane may be adjusted. According to further embodiments of the present invention, movement of either the conversion surface, the concentrator surface, or both may be constrained such that the two surfaces remain parallel to one another.

According to some embodiments of the present invention, a control circuit, including control logic, may cause the concentrator plane and/or the conversion plane to move relative to one another such that incident light entering the assembly from the outside is concentrated upon the photovoltaic active regions of the conversion plane. One or more light sensors functionally associated with the control circuit may provide directional information regarding an angle of incidence at which light enters the concentrator plane. The control circuit may cause the relative positions of the concentrator and conversion planes to be adjusted in response to a detected incident angle and to any change in the detected incident angle, such that light entering the assembly is substantially continually being concentrated on the PV active regions (e.g. mounted PV cells).

According to further embodiments of the present invention, the control circuit/logic may measure, estimate or otherwise derive a value associated with a derivative (i.e. rate of change) of incident angle over some period of the day. Based on the derivative of the incident angle, a corresponding derivative value associated with a rate of change in relative surface positions required to maintain light concentration on the PV regions may be calculated. According to further embodiments of the present invention, the control logic may be adapted to cause the electromechanical actuator(s) to substantially continually move one of the surfaces in accordance with one or both of the derivative values, or in accordance with a value derived from one the derivatives.

According to further embodiments of the present invention, a current, voltage and/or power measurement circuit may be functionally associated with the photovoltaic active regions and with the controller circuit. The control circuit may apply an iterative positioning algorithm using an output of the measurement circuit as its input in order to find a relative position between the concentrator plane and the conversion plane such that: (1) incident light concentrations on the photovoltaic active regions is optimized, and (2) power output of the photovoltaic active regions if substantially optimized/maximized given existing light conditions.

Relative positioning of the concentration and conversion planes may be adjusted in one, two or three dimensions. According to some embodiments of the present invention, such as those using line-focus (i.e. semi-cylindrical) concentrator structures and narrow (e.g. 2 mm wide) elongated photovoltaic active regions, one dimensional movement (horizontal: parallel to the planes/surface) of either the concentrator or conversion plane may be implemented. A further dimension (i.e. a second dimension) of movement, up and down—perpendicular to the concentrator/conversion planes, may also be implemented along with the horizontal/parallel position adjustment described above for embodiments including line-focus structures. Movement in each of the dimensions may be achieved by one or more actuators. According to some embodiments, one actuator may facilitate movement in two or more dimensions. One or more actuators and guiding structures (e.g. tracks) used for moving the conversion surface and/or concentrator plane relative to one another may be adapted to maintain parallel spatial relations between the conversion surface and the concentrator plane.

According to other embodiments of the present invention, such as those using dot focus (e.g. semi-spherical) concentrator structures and round/square/dot shaped photovoltaic active regions, three dimensional movement (two dimensions horizontally, parallel to the planes, and one-dimensional movement perpendicular to either the concentrator or conversion planes) may be implemented. Movement in each of the dimensions may be achieved by one or more actuators. According to some embodiments, one actuator may facilitate movement in two or more dimensions. One or more actuators and guiding structures (e.g. tracks) used for moving the conversion surface and/or concentrator plane relative to one another may be adapted to maintain parallel spatial relations between the conversion surface and the concentrator plane.

According to further embodiments of the present invention, photovoltaic active regions may include or be coated with a light diffusion layer adapted to defuse light concentrated on a portion of a given photovoltaic active region across a larger portion of the given photovoltaic active region.

According to further embodiments of the present invention, the assembly may include either a heat collection or a cooling sub-system. One or more evaporator stages of a cooling system may be functionally (e.g. thermally) connected with the conversion surface or backplane. The evaporation stage may be integral with the backplane of the conversion surface/plane and/or may be thermally coupled to an underside (i.e. surface opposite the surface of the photovoltaic active regions) of the backplane. Heat conveyed away from the substrate may be used to heat a hot water tank or to generate steam used to drive a turbine. Any heat collection and utilization system known today or to be devised in the future may be applicable to the present invention. Alternatively, heat sink (e.g. heat conducting fins) may be used to convey heat away from the backplane.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1A shows a perspective view of an exemplary light based electrical power generation assembly/unit according to embodiments of the present invention utilizing line-focus (e.g. substantially semi-cylindrical) concentrator structures and narrow elongated PV cells;

FIG. 1B shows a perspective view of an exemplary light based electrical power generation assembly/unit according to embodiments of the present invention utilizing dot-focus (e.g. substantially semi-spherical) concentrator structures and square or dot shaped PV cells;

FIG. 1C. shows a perspective view of an exemplary light based electrical power generation assembly/unit according to embodiments of the present invention utilizing Fresnel concentrator structures arranged in a dot-focus configuration and square or dot shaped PV cells;

FIG. 2A is a cross sectional view of an assembly according to some embodiments of the present invention;

FIG. 2B is a second cross sectional view of the assembly according to embodiments of the present invention where a relative position between the concentrator plane and the conversion surface has change to compensate for a shift in position of the sun;

FIG. 3 is a functional block diagram of a unit/assembly controller according to some embodiments of the present invention.

FIG. 4A is a top view of an exemplary conversion surface according to embodiments of the present invention where photovoltaic active regions are composed of narrow elongated photovoltaic cells affixed to a backplane;

FIG. 4B is a top view of an exemplary conversion surface according to embodiments of the present invention where photovoltaic active regions are composed of square shaped photovoltaic cells affixed to a backplane;

FIG. 4C is a top view of an exemplary conversion surface according to embodiments of the present invention where photovoltaic active regions are composed of dot shaped photovoltaic cells affixed to a backplane;

FIG. 5 is a bottom view of an exemplary backplane according to an embodiment of the present invention where a heat removal structure is thermally connected; and

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

Unless specifically stated otherwise, as apparent from the following discussions, it is appreciated that throughout the specification discussions utilizing terms such as “processing”, “computing”, “calculating”, “determining”, or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Embodiments of the present invention may include apparatuses for performing the operations herein. This apparatus may be specially constructed for the desired purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, magnetic-optical disks, read-only memories (ROMs), random access memories (RAMs) electrically programmable read-only memories (EPROMs), electrically erasable and programmable read only memories (EEPROMs), magnetic or optical cards, or any other type of media suitable for storing electronic instructions, and capable of being coupled to a computer system bus.

The processes and displays presented herein are not inherently related to any particular computer or other apparatus. Various general purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the inventions as described herein.

### General Embodiments

According to some embodiments of the present invention, a light based electrical power generation unit or assembly may include a concentrator plane including one or more photo-concentrator structures. The unit may also include a conversion surface including one or more photovoltaic (“PV”) active regions, and the conversion surface may be substantially parallel to the concentrator plane. A first actuator may adjust a relative position between the concentrator plane and the conversion surface while maintaining substantially parallel relations between the concentrator plane and the conversion surface. The first actuator and/or a combination of actuators may adjust a relative position between the concentrator plane and the conversion surface horizontally (i.e. parallel to the concentrator plane in one or two dimensions) and/or vertically (i.e. perpendicular to the concentrator plane). According to further embodiments of the present invention one or more tracks, to which either the concentrator plane and/or the conversion surface may be slideably affixed, may maintain a substantially parallel relation between the concentrator plane and the conversion surface.

According to further embodiments of the present invention, the unit may include or be functionally associated with one or more light sensors adapted to generate an electric signal indicative of an angle of incidence of sunlight entering or striking the concentrator plane. A control circuit integral or functionally associated with the unit or assembly may receive the signal from the sensor and may generate a control signal to the first actuator, wherein the signal is based on the sensor(s) signal or based on a derivative of the sensor(s) signal. The control signal may be adapted to cause the first actuator, another actuator, or a set of actuators working in concert to change the relative positions between the concentrator plane and the conversion surface so as to position one or more PV active regions of the conversion surface at or near one or more light concentration regions produced by light passing through one or more concentrator structures of the concentrator plane.

According to further embodiments of the present invention, the concentrator structures may be composed of non-planar mirrors arranged under the conversion surface. According to these embodiments, the conversion surface may be clear, the concentrator plane may be located below the conversion surface, and PV active regions on the conversion surface may face downward towards the concentrator plane. Each of some of all of a set non-planer mirrors may focus light onto a separate PV active region.

According to some embodiments of the present invention, the control signal is adapted to cause the first actuator to adjust a relative position of said concentrator plane and the conversion surface in a direction parallel to the concentrator plane. The control signal may also be adapted to cause the first or a second actuator to adjust a relative position of the concentrator plane and said conversion surface in a direction perpendicular to said concentrator plane. The first and/or the second actuators may be of a type selected from the group consisting of mechanical actuators, electromechanical actuators, pneumatic actuators and thermal actuators.

The one or more concentrator structures may be structures selected from the group consisting of dot-focus or line-focus lenses such as substantially semi-cylindrical lenses, substantially semi-spherical lenses, convex lenses, Fresnel lenses and curved mirrors.

The one or more PV active regions may be comprised of PV cells attached to or grown on a backplane of said conversion surface. The active regions may include a diffusion layer on at least one of said PV active regions. The backplane may be composed of an electrically isolative material which may also be a thermally conductive material. The backplane may include at least one electrically conductive path, which conductive paths may be configured to aggregate current from two or more PV active regions at or near an output terminal of said backplane.

According to some embodiments of the present invention, the unit or assembly may include a heat removal structure. The heat removal structure may be associated with a cogeneration system or with a water heating system.

### Embodiment 1

According to embodiment 1 of the present invention, either East/West or North/South tracking or both may be employed. Sunlight is concentrated and focused into dots or lines by a planar array of lenses that faces the sunlight, onto a planar array of photovoltaic (PV) material elements that is parallel to the lens array. An array of PV dot or strips may be formed with the same or similar spacing (pitch) as the array of lenses.

The PV strip array may be parallel or almost parallel to the focal plane(s) of the lenses. The PV elements may thus be illuminated and may be used to generate electrical voltage and current. A number of PV elements may be connected in series through switches in order to achieve a desired voltage. A number of such strings may be connected in parallel, through switches, in order to achieve the desired current and power output. Any combination of PV elements may connected in series by a first (optionally: computer controllable) switch or first set of switches. The out of the switch or first set of switches may set be of connected parallel by a second (optionally: computer controllable) switch or set of switches.

Lenses of the lens array may be of Fresnel type or of any other type of lenses, and may have cylindrical, circular or other symmetry.

Sun tracking may be performed in one dimension—either East/West or North/South—by changing the respective positions of a lens array and a PV array, in lateral shift, with sunlight focused into lines using lenses with line-focusing property, onto corresponding elongated, narrow strips of PV material (“line focus”).

Sun tracking may be performed in two dimensions by changing the respective positions of a lens array and the PV array, using lateral shift, with sunlight focused into dots using lenses with dot-focusing property, onto corresponding small patches of PV material (“dot focus”).

Lens and PV arrays may be connected by a flexible support, such as a thin metal strip or a rotary spring. The deformation of the flexible support may be such that distance between arrays change simultaneously with relative lateral shift between the arrays, (in a direction perpendicular to the plane of the arrays) in order to compensate for defocusing caused by the change of light incidence angle.

A light position detector may detect position of focused lines or points of light, and feed position information to a controller. A controller—implemented as a microprocessor or an analog control system or a digital control system and/or a digital control algorithm—uses position information from a light position detector in order to issue corrective control signals to actuators so as to optimize the position of light focus and spread the maximal portion of the collected light on PV elements.

One or more voltage/current measurement circuits functionally associated with a (e.g. positioning) controller may monitor the output of the PV cells and an algorithm running on the controller may search for an optimal position, which search may be based on iterative two-dimensional positioning scans for the line focused case (one dimension lateral shift and one dimension for focusing shifts). The search may be based on iterative three-dimensional scans for the dot-focus case.

Actuators—electrical, thermal, hydraulic or of any other type—may be used in order to move lens array with respect to PV array, or vice versa, with lens array remaining parallel to PV array, so as to keep light focused on PV elements, based on corrective signals received from a controller.

A power supply regulator may be connected to an electrical outlet of a PV array, in order to generate and feed power supply to electrically operated parts of the apparatus—which may be actuators, controller, light position detector and/or any other electrically operated components or circuits.

A system comprising a lens array, PV array, controller, light position detector, actuators, power supply regulator and supporting mechanical structures may be enclosed in a mechanical enclosure, which may be hermetically sealed and filled with air or other gas, and which may have one side implemented as a transparent flat panel that may substantially face the sun. The transparent panel may include one or more concentrator structures and may act as a concentrator surface. The enclosure may protect the rest of the apparatus from environmental factors. The enclosure may have an interface to the outside, which interface may have electrical contacts for carrying generated electrical power out and for receiving control signals from the outside.

### DESCRIPTION OF FIGURES

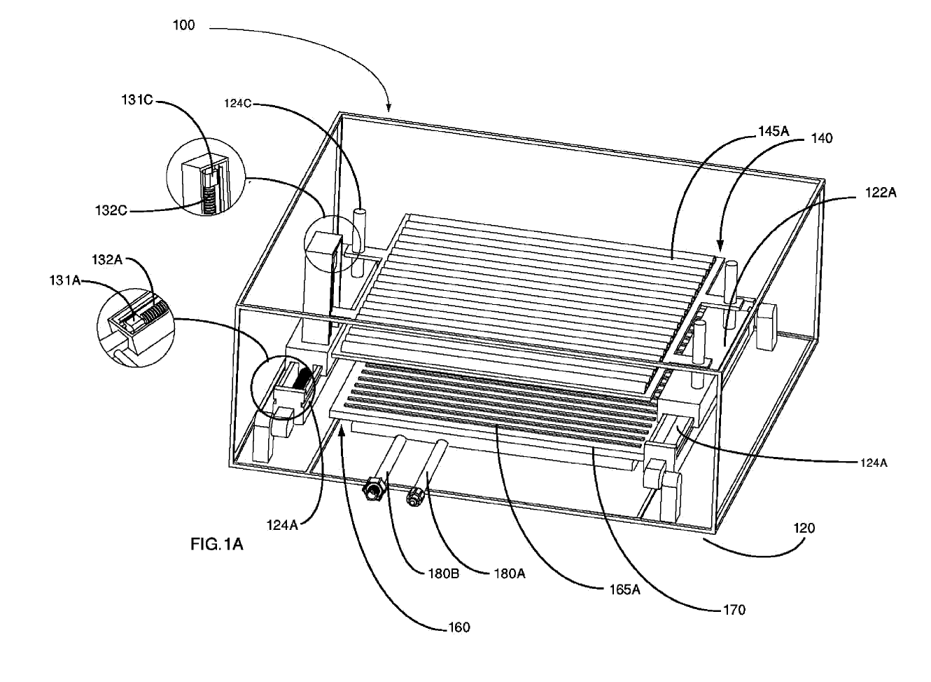

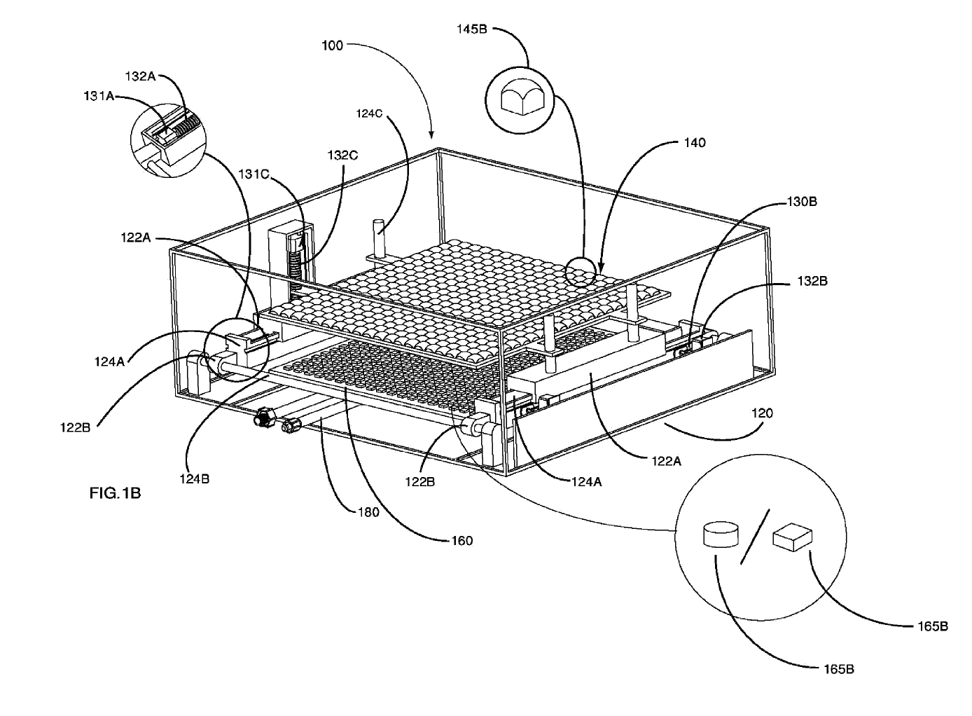

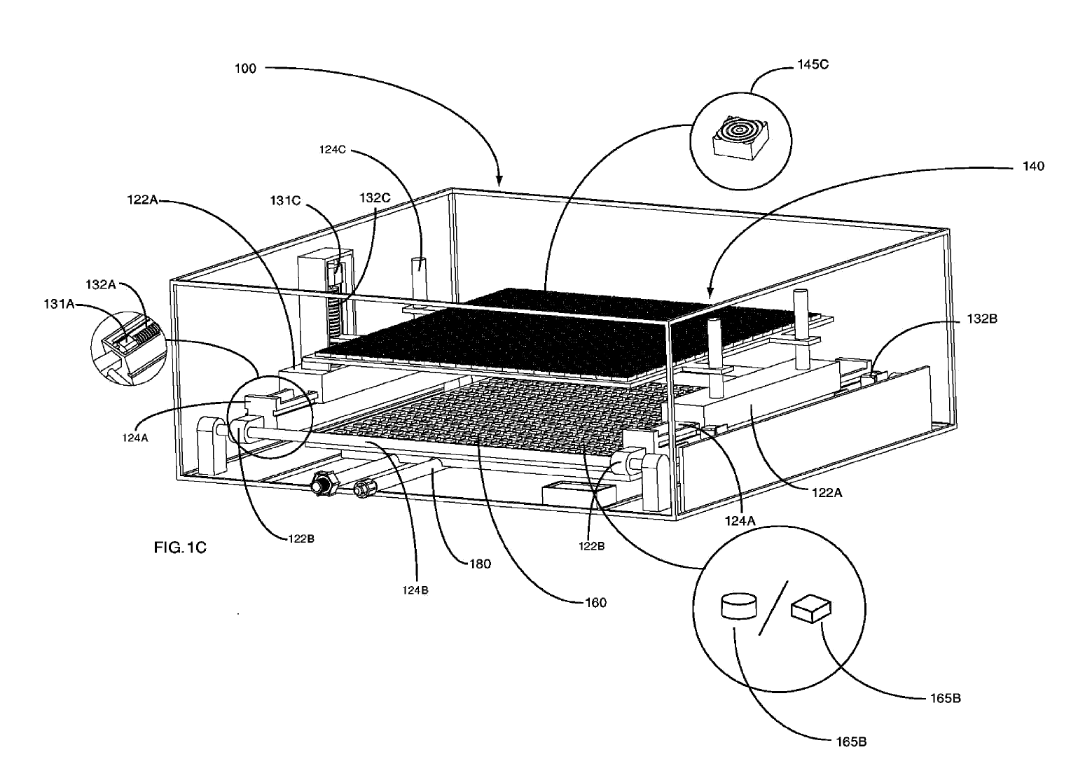

Turning now to FIG. 1A, there is shown a perspective view of an exemplary light based electrical power generation assembly/unit 100 according to embodiments of the present invention. The embodiment of FIG. 1A utilizes line-focus (e.g. substantially semi-cylindrical) concentrator structures 145A and narrow elongated PV cells 165A. The concentrator structures 145A are part of and/or reside upon a concentrator plane 140 which is mounted on vertical tracks 124C perpendicular to the plane 140. A vertical actuator 130C, in the form of a threaded bar 132C rotated by an electric motor 131C, is adapted to adjust the position of the concentrator plane 140 along the vertical tracks 124C. The vertical tracks 124C are mounted on support structure 122A slideably connected to first horizontal tracks 124A, and a position of the support structure 122A may be adjusted by a first horizontal actuator 130A, which first horizontal actuator 130A is in the form of a threaded bar 132A rotatable by a connected electric motor 131A. Heat exchange/removal conduits 180A and 180B, which are part of a heat removal system, are protruding from the bottom of the conversion surface backplane 170.

Turning now to FIG. 1B, there is shown a perspective view of an exemplary light based electrical power generation assembly/unit 100 according to embodiments of the present invention utilizing dot-focus (e.g. substantially semi-spherical) concentrator structures 145B and square or dot shaped PV cells 165B. The concentrator structures 145B according to this embodiment may be substantially semi-spherical or any other dot focusing geometry. The embodiment of FIG. 1B may include second horizontal tracks 124B which are perpendicular to the first horizontal tracks 124A and to the vertical tracks 124C. The first horizontal tracks 124A may be mounted on a support structure 122B slideably connected to the second horizontal tracks 124B and a second horizontal actuator 130B may be adapted to adjust the position of the first horizontal tracks' support structure 122B on the second horizontal tracks 124B. The combination and arrangement of horizontal tracks and horizontal actuators provide for two dimensional horizontal position adjustment of the concentrator plane.

Turning now to FIG. 1C, there is shown a perspective view of an exemplary light based electrical power generation assembly/unit 100 according to embodiments of the present invention utilizing Fresnel concentrator structures 145C arranged in a dot-focus configuration and square or dot shaped PV cells. The embodiment according to FIG. 1C is identical to the one in FIG. 1B, except for the use of Fresnel concentrator structures 145C.

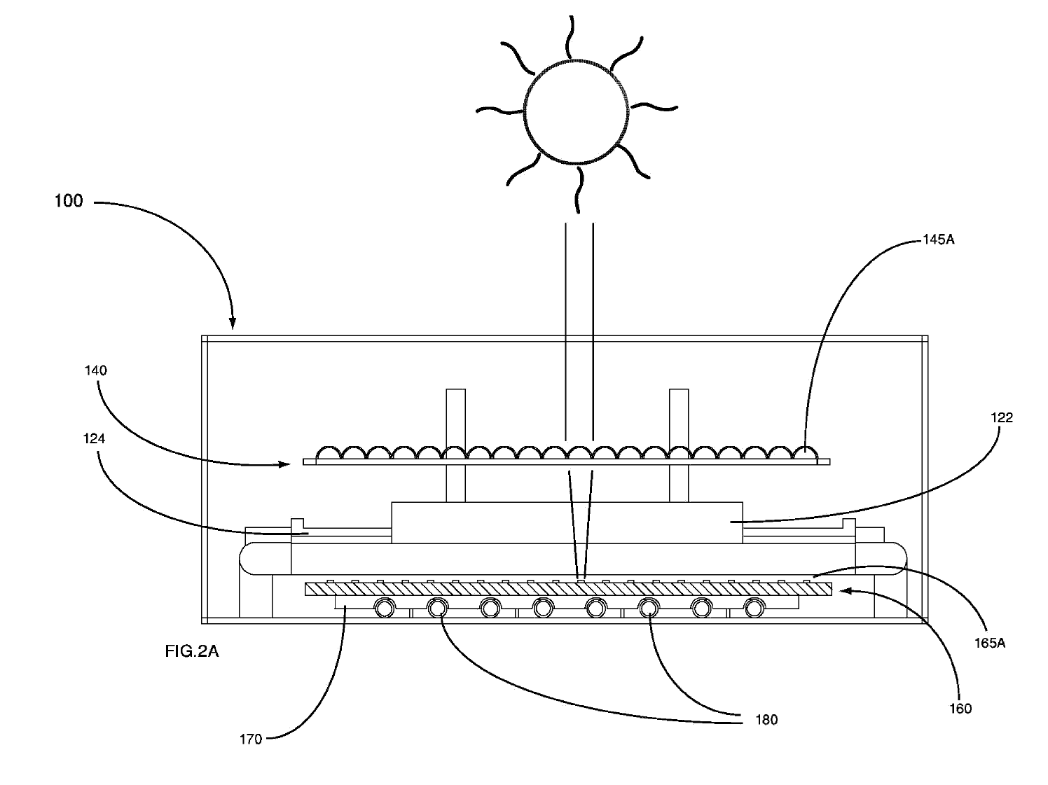

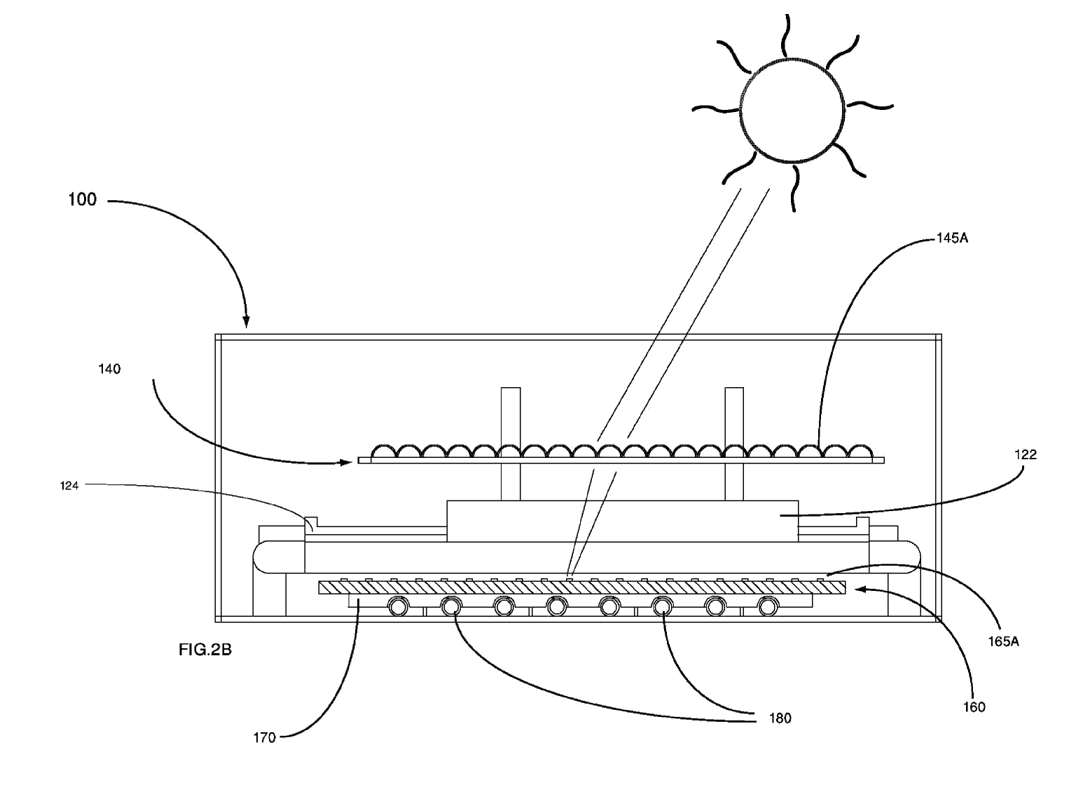

Turning now to FIG. 2A, there is shown a cross sectional view of an assembly according to some embodiments of the present invention. FIG. 2A depicts sun rays being substantially perpendicular to the concentrator plane and the rays being focused by each concentrator structure onto a PV active region substantially directly below the concentrator structure. FIG. 2B is a second cross sectional view of the assembly of FIG. 2A, where a relative position between the concentrator plane and the conversion surface has been changed in order to compensate for a shift in position of the sun a resulting shift position of the concentrator structures' focal point(s).

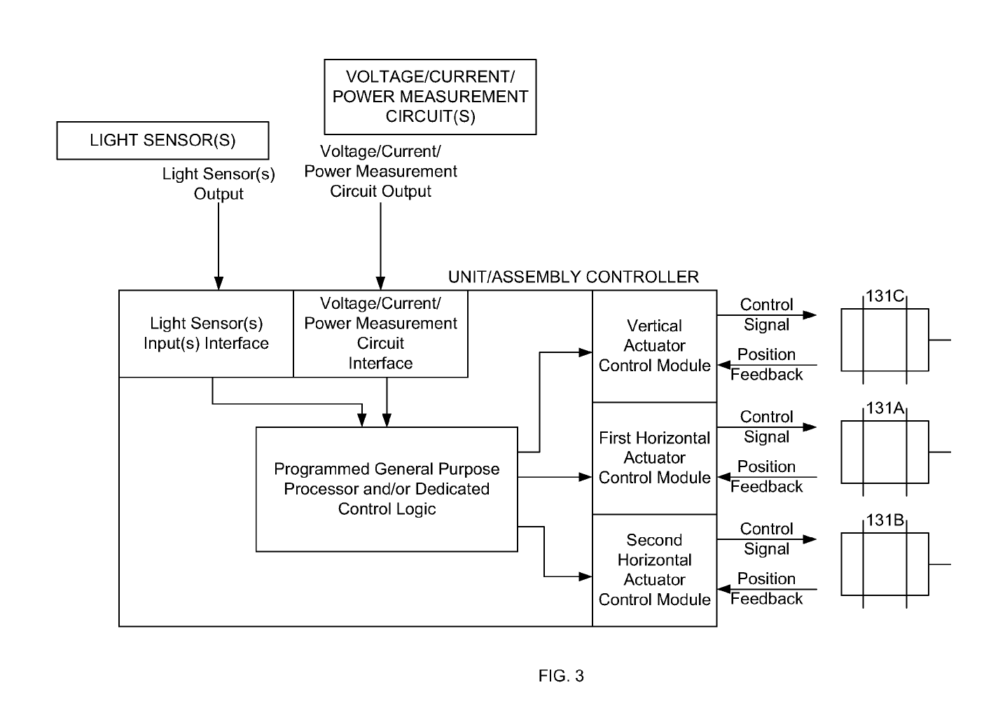

Turning now to FIG. 3, there is shown a functional block diagram of a unit/assembly controller according to some embodiments of the present invention. The controller includes separate control modules for each of a vertical, first horizontal and second horizontal actuators. The modules may include positioning feedback inputs adapted to receiving positioning information from position encoders functionally associated with the actuators, thereby facilitating accurate positioning of the actuators. The controller may also include input modules for receiving signals from either a light sensor(s) and/or a voltage/current/power measurement circuit. A processor or dedicated control logic may derive an intended position for each of the actuators functionally associated with each of the modules based on signals received from the light sensor(s) and/or from the measurement circuit(s). The processor or control logic may execute one or more (e.g. scanning) algorithms to determine an (e.g. optimal) intended relative positioning between the concentrator plane and conversion surface given a current position of the sun. Mapping tables or translation functions used by the controller may convert/map an intended relative positioning between the plane and the surface into actuator positions. The controller may substantially continuously cause the actuators to change position as the position of the sun changes.

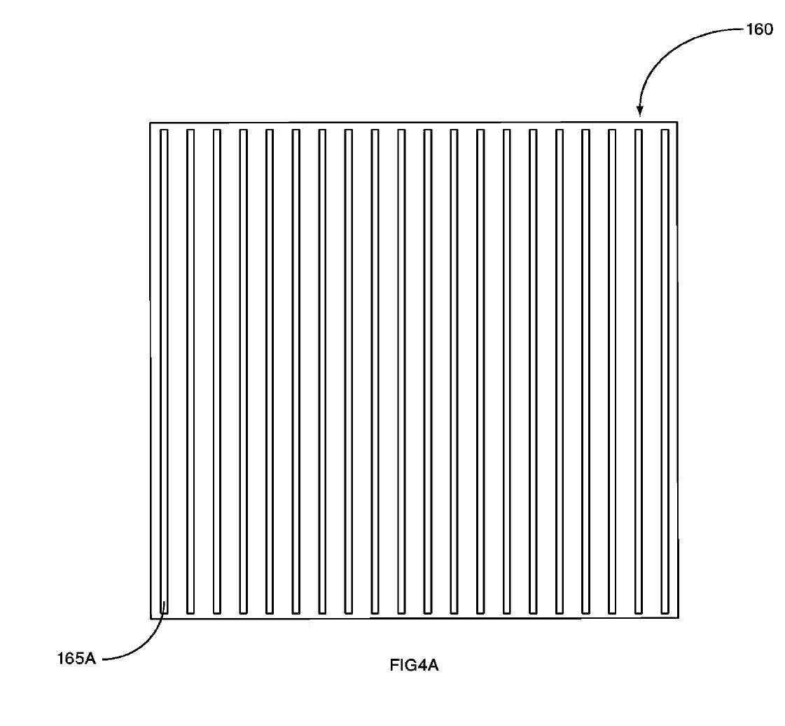

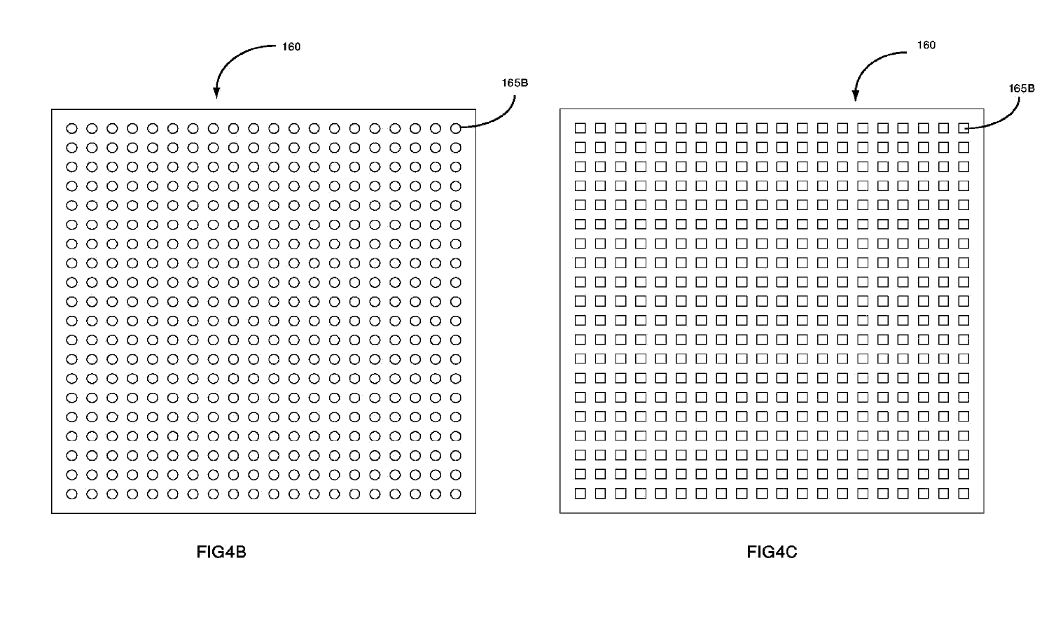

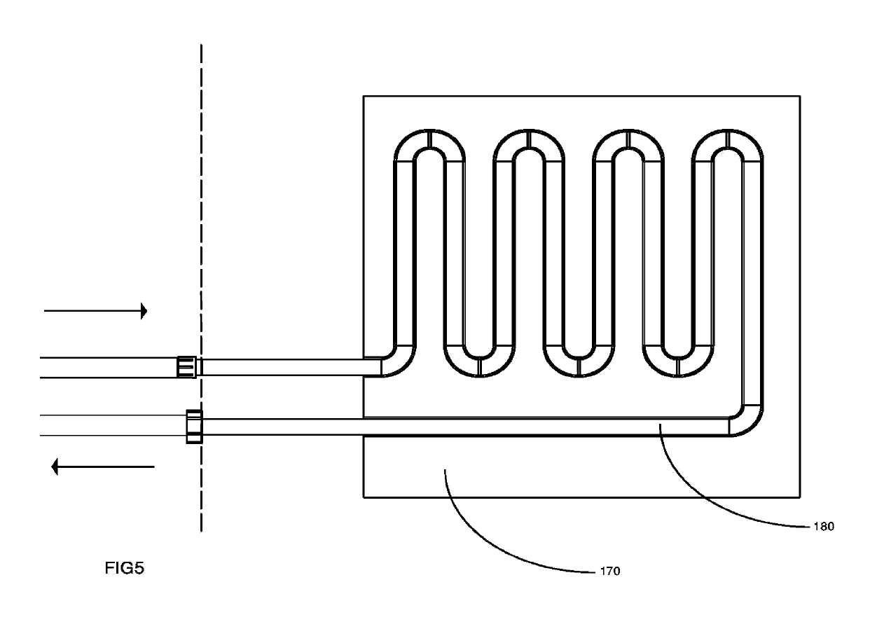

Turning now to FIG. 4A, there is shown a top view of an exemplary conversion surface 160 according to embodiments of the present invention where photovoltaic active regions are composed of narrow elongated photovoltaic cells 165A affixed to a backplane 170. FIG. 4B is a top view of an exemplary conversion surface 160 according to embodiments of the present invention where photovoltaic active regions are composed of square shaped photovoltaic cells 165B affixed to a backplane 170. FIG. 4C is a top view an exemplary conversion surface according to embodiments of the present invention where photovoltaic active regions are composed of dot shaped photovoltaic cells affixed to a backplane.

FIG. 5 is a bottom view of an exemplary backplane 170 according to an embodiment of the present invention, where a heat removal structure 180 is thermally connected. According to the embodiment of FIG. 4, the heat removal structure 180 is an evaporator tube/coil of a heat exchange/removal system. However, it should clear to one of ordinary skill in the art that any heat removal structure may be applicable to the present invention.

Certain features of the embodiments, which may have been, for clarity, described in the context of separate embodiments, may also be provided in various combinations in a single embodiment. Conversely, various features of the embodiments, which may have been, for brevity, described in the context of a single embodiment, may also be provided separately or in any suitable sub-combination.

The embodiments are not limited in their applications to the details of the order or sequence of steps of operation of methods, or to details of implementation of devices, set in the description, drawings, or examples. Moreover, the individual blocks illustrated in the block diagrams herein may be functional in nature and do not necessarily correspond to discrete hardware elements.

While the methods disclosed herein have been described and shown with reference to particular steps performed in a particular order, it will be understood that these steps may be combined, sub-divided, or reordered to form an equivalent method without departing from the teachings of the embodiments. Accordingly, unless specifically indicated herein, the order and grouping of the steps is not a limitation of the embodiments.

Any citation or identification of any reference in this application shall not be construed as an admission that such reference is available as prior art to the embodiments of the present invention.

While the embodiments have been described in conjunction with specific examples thereof, it is to be understood that they have been presented by way of example, and not limitation. Moreover, it is evident that many alternatives, modifications and variations will be apparent to those skilled in the art. Accordingly, it is intended to embrace all such alternatives, modifications and variations that fall within the spirit and scope of the appended claims and their equivalents. In the claims, means-plus-function clauses are intended to cover the structures described herein as performing the recited function and not only structural equivalents, but also equivalent structures.

Insofar as the description above and the accompanying drawings disclose any additional matter that is not within the scope of the claims below, the additional matter is not dedicated to the public and the right to file one or more applications to claim such additional inventions is reserved. Although very narrow claims are presented herein, it should be recognized that the scope of this invention is much broader than presented by the claims. It is intended that broader claims will be submitted in an application that claims the benefit of priority from this application.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

What is claimed:

1. A light based electrical power generation unit comprising:
a concentrator plane including one or more photo-concentrator structures;
a conversion surface including one or more photovoltaic (“PV”) active regions, wherein said conversion surface is substantially parallel to said concentrator plane; and
a first actuator adapted to adjust a relative position between said concentrator plane and said conversion surface while maintaining the parallel relation between said concentrator plane and said conversion surface.

2. The unit according to claim 1, further comprising a light sensor adapted to generate a signal indicative of an angle of incidence of light entering said concentrator plane.

3. The unit according to claim 2, further comprising a control circuit adapted to receive the signal from said sensor and to generate a control signal to said first actuator based on the sensor signal or based on a derivative of the sensor signal.

4. The unit according to claim 3, wherein the control signal is adapted to cause said first actuator to position one or more PV active regions at or near one or more light concentration regions produced by light passing through said one or more concentrator structures.

5. The unit according to claim 4, wherein said control signal is adapted to cause said first actuator to adjust a relative position of said concentrator plane and said conversion surface in a direction parallel to said concentrator plane.

6. The unit according to claim 4, wherein said control signal is adapted to cause said first actuator to adjust a relative position of said concentrator plane and said conversion surface in a direction perpendicular to said concentrator plane.

7. The unit according to claim 1, wherein said one or more concentrator structures is a structure selected from the group consisting of lenses having line-focus or dot-focus property.

8. The unit according to claim 1, wherein said one or more PV active regions are comprised of PV cell attached to or grown on a backplane of said conversion surface.

9. The unit according to claim 8, wherein said backplane includes of at least one electrically conductive path.

10. The unit according to claim 8, wherein said backplane is comprised of an electrically isolative material.

11. The unit according to claim 8, wherein said backplane is comprised of a thermally conductive material.

12. The unit according to claim 9, wherein said electrically conductive paths are configured to aggregate current from two or more PV active regions at or near an output terminal of said backplane.

13. The unit according to claim 1, wherein said first actuator is an actuator of a type selected from the group mechanical actuator, electromechanical actuator, pneumatic actuator and thermal actuator.

14. The unit according to claim 13, further comprising at least a second actuator which is either of the same or different type as said first actuator.

15. The unit according to claim 1, further comprising a light diffusion layer on at least one of said PV active regions.

16. The unit according to claim 1, further comprising a heat removal structure.

17. The unit according to claim 16, wherein said heat removal structure is associated with a heat/electricity co-generation system.

18. The unit according to claim 16, wherein said heat removal structure is associated with a water heating system.

19. The unit according to claim 1, further comprising a measurement circuit adapted to measure current and/or voltage from said one or more photovoltaic (“PV”) active regions.

20. The unit according to claim 19, further comprising a control circuit adapted to receive the signal from said measurement circuit and to generate a control signal to said first actuator based on the measurement circuit signal.

21. The unit according to claim 20, wherein the control signal is adapted to cause said first actuator to position one or more PV active regions at or near one or more light concentration regions produced by light passing through said one or more concentrator structures.

22. A method of electrical power generation comprising:
adjusting a relative position between a concentrator plane and a conversion surface while maintaining a parallel relation between the concentrator plane and the conversion surface.

23. The method of claim 22, further comprising deriving an angle of incidence of light entering the concentrator plane.

24. The method of claim 23, further comprising adjusting the relative position based on the derived angle.

25. The method of claim 22, further comprising measuring one or more parameters of a power output from photovoltaic regions (“PV”) of the conversion surface.

26. The method of claim 25, further comprising adjusting the relative position based on the measured one or more parameters.

27. The method of claim 26, wherein adjusting the relative position includes positioning one or more photovoltaic active regions on the conversion surface at or near one or more light concentration regions produced by light passing through the concentrator plane.
